(19) United States
(12) Patent Application Publication
(10) Pub. No.: US 2010/0039772 A1
(43) Pub. Date: Feb. 18, 2010

(54) Cooling device and electronic device

(75) Inventors: Kazuhiro NITTA, Kawasaki (JP); Masumi SUZUKI, Kawasaki (JP); Michimasa AOKI, Kawasaki (JP); Keizou TAKEMURA, Kawasaki (JP); Kenji KATSUMATA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kanagawa (JP)

(21) Appl. No.: 12/588,662

(22) Filed: Oct. 22, 2009

Related U.S. Application Data
(62) Division of application No. 11/362,924, filed on Feb. 28, 2006.
Application No. 11/362,924 is a continuation of application No. PCT/JP04/16239, filed on Nov. 1, 2004.

(30) Foreign Application Priority Data
Oct. 30, 2003 (JP) 2003-370971

(51) Int. Cl. H05K 7/20

(52) U.S. Cl. 361/697

(57) ABSTRACT

In a cooling device, an electronic component is attached to one surface on one side of a heat pipe so that heat can be conveyed, a first heat-radiating fin is provided on another surface on another side of the heat pipe, a first fan unit that sends an airflow to the first heat-radiating fin is provided on one side of the heat pipe, and a first duct that guides the airflow produced by the first fan unit to the first heat-radiating fin is provided on the other surface of the heat pipe.

### CROSS-REFERENCE TO RELATED APPLICATIONS

This application claims the benefit of Japanese Application No. 2003-370971, filed Oct. 30, 2003, the disclosure of which is incorporated herein by reference. This application is a divisional application of U.S. application Ser. No. 11/362,924, filed Feb. 28, 2006, now pending and incorporated by reference herein.

### BACKGROUND OF THE INVENTION

1. Field of the Invention

The present invention relates to cooling devices used for cooling down electronic components in electronic device.

2. Description of the Related Art

Electronic components used in personal computers etc. (for example, microprocessors (MPU), graphic chips, etc.) generate heat. The operation of the electronic component generally becomes unstable if the temperature of an electronic component exceeds a certain value. Therefore, generally a cooling device is used to cool down electronic components that generate a large amount of heat are provided with a cooling device. An example of a cooling device is shown in FIG. 7.

In the example of FIG. 7, an electronic component 3 that generates heat is attached onto one side of a planer heat pipe 1. A heat radiating fin 7 and a fan unit 9, which is adjacent to the heat radiating fin 7, for producing airflow near the heat radiating fin 7 are provided on another side of the heat pipe 1.

The heat pipe 1 encloses in an airtight container a small amount of liquid called operating fluid (purified water or chlorofluorocarbon, etc.) in a vacuum state. A mesh type material called a wick, which has a capillary structure, is lined inside the container.

The operation of cooling is performed as follows. The fan unit 9 creates an airflow near the heat radiating fin 7 to cool the heat radiating fin 7. When the electronic component 3 generates heat, the operating fluid evaporates at a position of the heat pipe 1 to which the electronic component 3 is attached. The vapor of the operating fluid moves towards the heat radiating fin 7. The heat radiating fin 7, which is at a lower temperature than the hot vapor, absorbs heat from the hot vapor. As a result, the vapor gets cooled and condensed. The condensed operating fluid returns to the position to which the electronic component 3 is attached due to a capillary phenomenon. The cycle of evaporation, movement, and condensation is repeated so that the heat of the electronic component 3 is continuously conveyed to the heat radiating fin 7.

In other words, the heat of the electronic component 3 is quickly conveyed to the heat radiating fin 7 through the heat pipe 1, transferred to the airflow produced by the fan unit 9, and discharged outside.

A conventional technology has been disclosed in, for example, Japanese Patent Application Laid Open No. 2002-76223 (see pages 4 to 5, FIG. 1).

However, in the cooling mechanism shown in FIG. 7, the electronic component 3, the fan unit 9, and the heat radiating fin 7 are provided in this order on one surface of the heat pipe 1, and the heat radiating fin 7 and the fan unit 9 are adjacent to each other. Accordingly, a problem arises in that an airflow produced by the fan unit 9 does not flow evenly throughout the entire heat radiating fin 7, and therefore, the cooling ability is low.

The present invention has been made in view of the above problems. An object of the present invention is to provide a compact cooling device for an electronic component with improved cooling ability.

### SUMMARY OF THE INVENTION

It is an object of the present invention to at least solve the problems in the conventional technology.

According to an aspect of the present invention, a cooling device includes a heat pipe; an attaching member that attaches an electronic component to one surface on one side of the heat pipe so that the heat pipe can absorb heat of the electronic component; a first heat-radiating fin attached to another surface on another side of the heat pipe; a first fan unit that produces an airflow and directs the airflow toward the first heat-radiating fin; and a first duct that guides the airflow produced by the first fan unit to the first heat-radiating fin.

According to another aspect of the present invention, an electronic device includes an electronic component; and a cooling unit. The cooling unit includes a heat pipe; an attaching member that attaches an electronic component to one surface on one side of the heat pipe so that the heat pipe can absorb heat of the electronic component; a first heat-radiating fin attached to another surface on another side of the heat pipe; a first fan unit that produces an airflow and directs the airflow toward the first heat-radiating fin; and a first duct that guides the airflow produced by the first fan unit to the first heat-radiating fin.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIGS. 1A and 1B are schematics of an arrangement according to a first embodiment of the present invention.

FIGS. 2A and 2B are schematics of an arrangement according to a second embodiment of the present invention.

FIGS. 3A and 3B are schematics of another arrangement according to a second embodiment of the present invention.

FIGS. 4A, 4B, and 4B are schematics of an arrangement according to a third embodiment of the present invention.

FIG. 5 is a schematic of an arrangement according to a fourth embodiment of the present invention.

FIGS. 6A and 6B are schematics of an arrangement according to a fifth embodiment of the present invention.

FIG. 7 is a perspective view of a conventional cooling device of an electronic component.

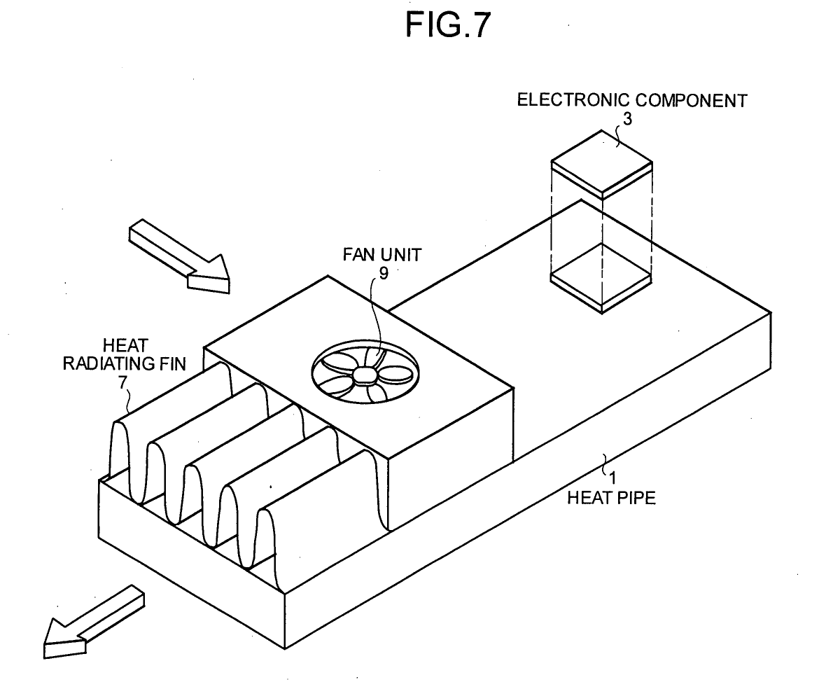

### DETAILED DESCRIPTION OF THE PREFERRED EMBODIMENTS

Exemplary embodiments of the present invention are explained in detail below with reference to the accompanying drawings.

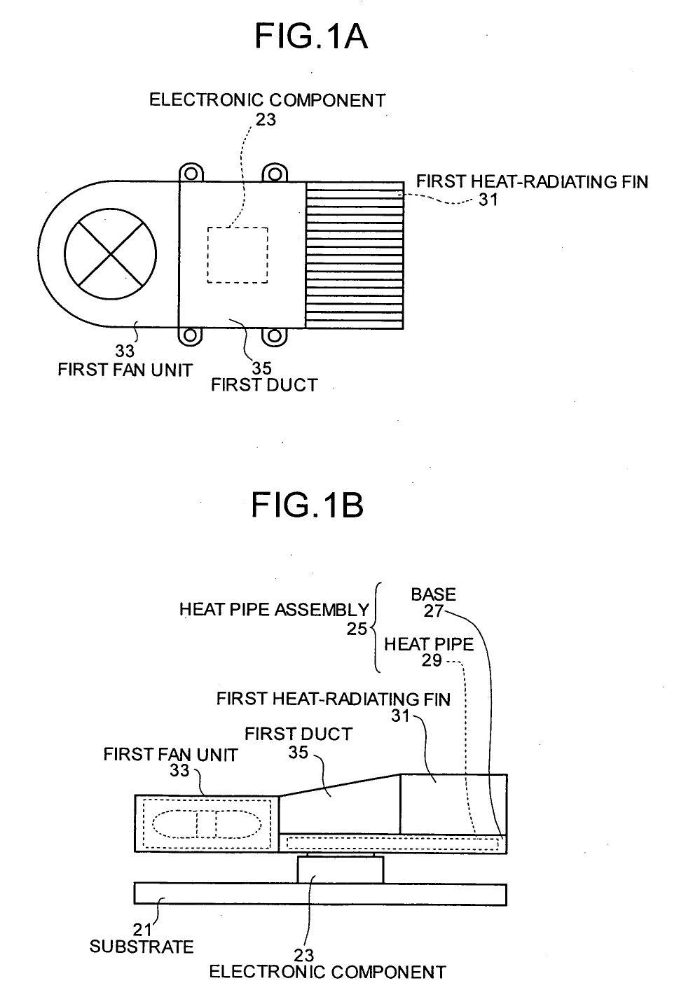

A first embodiment of the present invention is described below with reference to FIGS. 1A and 1B. FIG. 1A is a top view, and FIG. 1B is a side view of FIG. 1A.

As shown in the figures, an electronic component 23 that generates heat is provided on a substrate 21. A bottom surface (one surface) on one side of a planer heat pipe assembly 25 is attached on the electronic component 23. The heat pipe assembly 25 includes a base 27 made of a material of high heat conductivity and a planer heat pipe provided inside the base 27. A first heat-radiating fin is provided on a top surface (other surface) of the heat pipe assembly 25. A first fan unit 33 is provided on one side of the heat pipe assembly 25. Further, a first duct that guides an airflow produced by the first fan unit 33 to the first heat-radiating fin 31 is provided on the top surface of the heat pipe assembly 25.

An operation of cooling is performed in the following manner.

The first fan unit 33 produces airflow. The air flows through the first duct 35 to the first heat-radiating fin 31, where it is cooled. When the electronic component 23 generates heat, operating fluid evaporates at a position of the heat pipe 29 to which the electronic component 23 is attached. The vapor moves towards the first heat-radiating fin 31, which is at lower temperature than the vapor, where the vapor gets cooled and condensed. The condensed operating fluid returns to the position to which the electronic component 23 is attached due to a capillary phenomenon. The cycle of evaporation, movement, and condensation is repeated so that the heat of the electronic component 23 is continuously conveyed to the first heat-radiating fin 31.

In other words, the heat of the electronic component 23 is quickly conveyed to the first heat-radiating fin 31 through the heat pipe 29, transferred to the airflow produced by the first fan unit 33, and discharged.

According to the above configuration, the following effects can be obtained:

(1) The airflow generated by the first fan unit 33 is rectified in the first duct 35, and the rectified air reaches the first heat-radiating fin 31. In other words, the air flows evenly inside the first heat-radiating fin 31 thereby more efficiently cooling the first heat-radiating fin 31.

(2) The electronic component 23 is attached to the bottom surface (one surface) on one side of the heat pipe 29, the first heat-radiating fin 31 is provided on the top surface (another surface) on another side of the heat pipe 29, the first fan unit 33 is provided on one side of the heat pipe 29, and the first duct 35 that guides an airflow produced by the first fan unit 33 to the first heat-radiating fin 31 is provided on the top surface of the heat pipe 29. Therefore, the device can be made compact.

(3) The heat pipe 29 is planer. Therefore, an area of contact between the electronic component 23 and the first heat-radiating fin 31 is large, thermal resistance between the heat pipe 29 and the electronic component 23 and the first heat-radiating fin 31 is decreased, and cooling ability is improved.

The present invention is not limited to the above embodiment. The heat pipe 29 is planer in the above embodiment, but the heat pipe can be configured with a plurality of tubes.

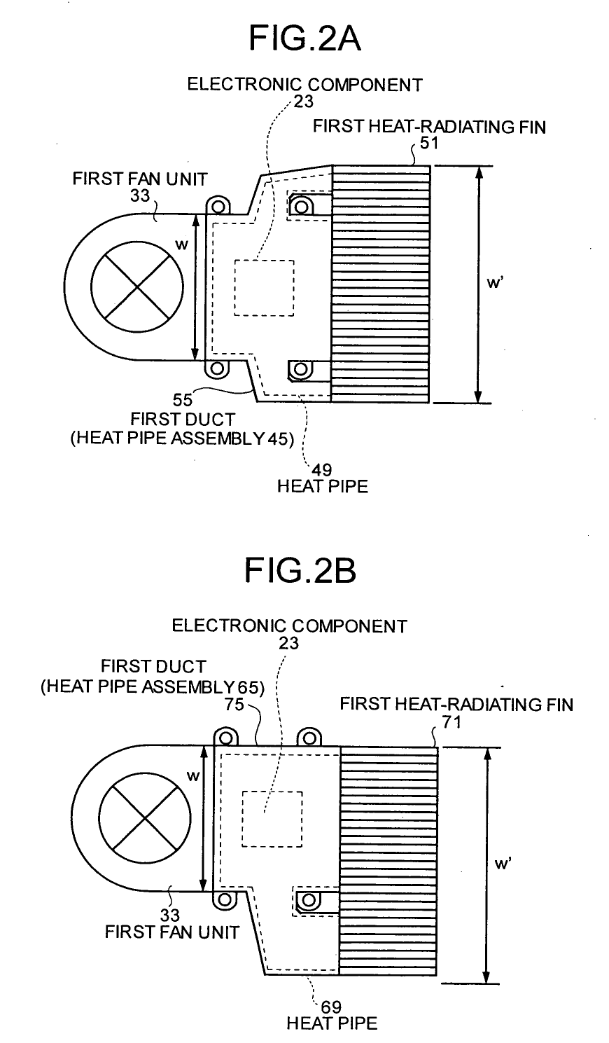

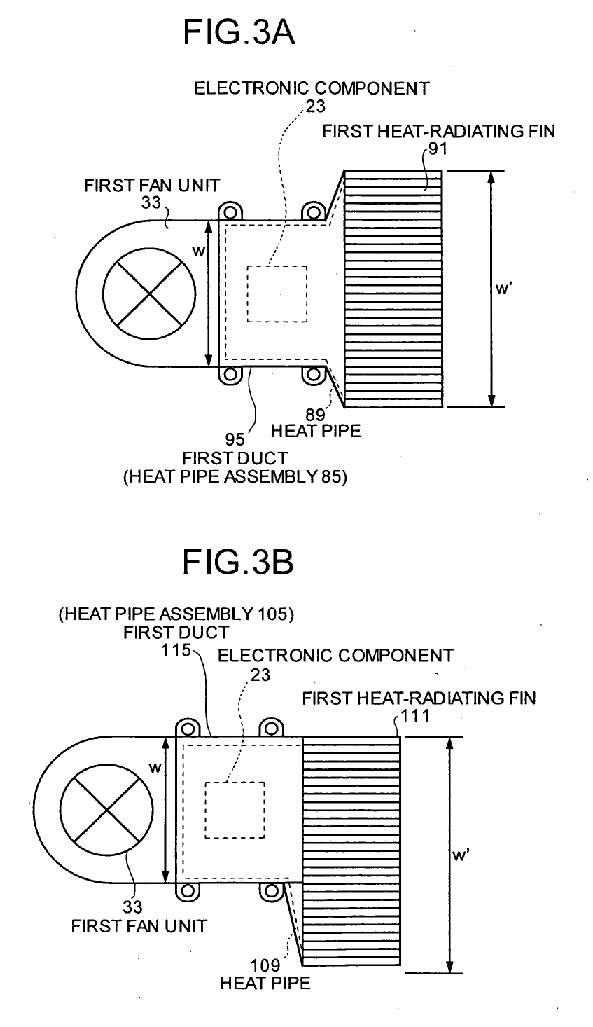

A second embodiment is described with reference to FIGS. 2A to 3B. The components in the second embodiment that perform same or similar function or that have same or similar configuration as those in the first embodiment are denoted by the same reference numerals as in the first embodiment, and overlapping descriptions are omitted.

First, in FIG. 2A, a planer heat pipe assembly 45 (a planer heat pipe 49) is configured such that a width (w′) of a side of the heat pipe assembly 45 (the heat pipe 49) on which a first heat-radiating fin 51 is provided is wider than a width (w) of a side of the heat pipe assembly 45 (the heat pipe 49) on which the electronic component 23 is attached. In FIG. 2A, both sides of the heat pipe assembly 45 (the heat pipe 49) are configured to spread out from a position where the electronic component 23 is attached.

A width of the first heat-radiating fin 51 is configured to match the width (w′) of the heat pipe assembly 45 (the heat pipe 49). Moreover, a first duct 55 is shaped to match the heat pipe assembly 45 (the heat pipe 49).

Thus the first heat-radiating fin 51 is wider than that in the first embodiment, i.e., the first heat-radiating fin 51 discharges a larger amount of heat, so that the cooling ability is further improved.

Next, in FIG. 2B, a planer heat pipe assembly 65 (a planer heat pipe 69) is configured such that a width (w′) of a side of the heat pipe assembly 65 (the heat pipe 69) on which a first heat-radiating fin 71 is provided is wider than a width (w) of a side of the heat pipe assembly 65 (the heat pipe 69) on which the electronic component 23 is attached. In FIG. 2B, one side of the heat pipe assembly 65 (the heat pipe 69) is configured to spread out from a position where the electronic component 23 is attached.

A width of the first heat-radiating fin 71 is configured to match the width (w′) of the heat pipe assembly 65 (the heat pipe 69). Moreover, a first duct 75 is shaped to match the heat pipe assembly 65 (the heat pipe 69).

Thus, the first heat-radiating fin 71 is wider than that in the first embodiment, i.e., the first heat-radiating fin 71 discharges a larger amount of heat, so that the cooling ability is further improved.

Next, in FIG. 3A, a planer heat pipe assembly 85 (a planer heat pipe 89) is configured such that a width (w′) of a side of the heat pipe assembly 85 (the heat pipe 89) on which a first heat-radiating fin 91 is provided is wider than a width (w) of a side of the heat pipe assembly 85 (the heat pipe 89) on which the electronic component 23 is attached. In FIG. 3A, both sides of the heat pipe assembly 85 (the heat pipe 89) are configured to spread out from near a position where the first heat-radiating fin 91 is provided.

A width of the first heat-radiating fin 91 is configured to match the width (w′) of the heat pipe assembly 85 (the heat pipe 89). Moreover, a first duct 95 is shaped to match the heat pipe assembly 85 (the heat pipe 89).

Thus, the first heat-radiating fin 91 is wider than that in the first embodiment, i.e., the first heat-radiating fin 91 discharges a larger amount of heat, so that the cooling ability is further improved.

Lastly, in FIG. 3B, a planer heat pipe assembly 105 (a planer heat pipe 109) is configured such that a width (w′) of a side of the heat pipe assembly 105 (the heat pipe 109) on which a first heat-radiating fin 111 is provided is wider than a width (w) of a side of the heat pipe assembly 105 (the heat pipe 109) on which the electronic component 23 is attached. In FIG. 3B, one side of the heat pipe assembly 105 (the heat pipe 109) is configured to spread out from near a position where the first heat-radiating fin 111 is provided.

A width of the first heat-radiating fin 111 is configured to match the width (w′) of the heat pipe assembly 105 (the heat pipe 109). Moreover, a first duct 115 is shaped to match the heat pipe assembly 105 (the heat pipe 109).

Thus, the first heat-radiating fin 111 is wider than that in the first embodiment, i.e., the first heat-radiating fin 111 discharges a larger amount of heat, so that the cooling ability is further improved.

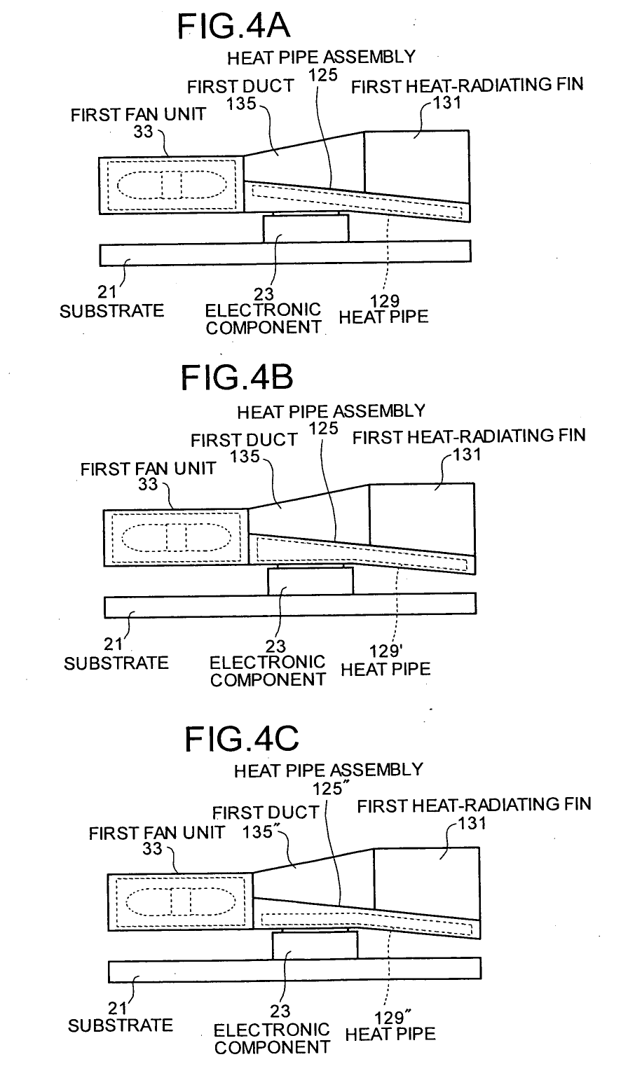

A third embodiment is described with reference to FIGS. 4A to 4C. The components in the third embodiment that perform same or similar function or that have same or similar configuration as those in the first embodiment are denoted by the same reference numerals as the first embodiment, and overlapping descriptions are omitted.

First, in FIG. 4A, a side of a planer heat pipe assembly 125 (a planer heat pipe 129) on which a first heat-radiating fin 131 is provided is slants towards the substrate 21. A first duct 135 is shaped to match the heat pipe assembly 125 (the heat pipe 129).

Thus, the first heat-radiating fin 131 is taller than that in the first embodiment, i.e., the first heat-radiating fin 131 discharges a larger amount of heat, so that the cooling ability is further improved.

Next, the shapes of the heat pipes are different in FIG. 4B and FIG. 4A. Specifically, a surface of a heat pipe 129′ facing the electronic component 23 is parallel to the electronic component 23.

According to the above configuration, a distance between the electronic component 23 and the heat pipe 129′ is decreased (thermal resistance is reduced), so that the cooling ability is further improved.

Lastly, the shape of the heat pipe assembly are different in FIG. 4C and FIG. 4A. Specifically, a heat pipe assembly 125″ (a heat pipe 129″) is bent in the middle so that a surface of the heat pipe assembly 125″ (the heat pipe 129″) facing the electronic component 23 is parallel to the electronic component 23. Moreover, a first duct 135″ is shaped to match the heat pipe assembly 125″ (the heat pipe 129″).

According to the above configuration, similarly to that of FIG. 4B, a distance between the electronic component 23 and the heat pipe 129″ is decreased (thermal resistance is reduced), so that the cooling ability is improved.

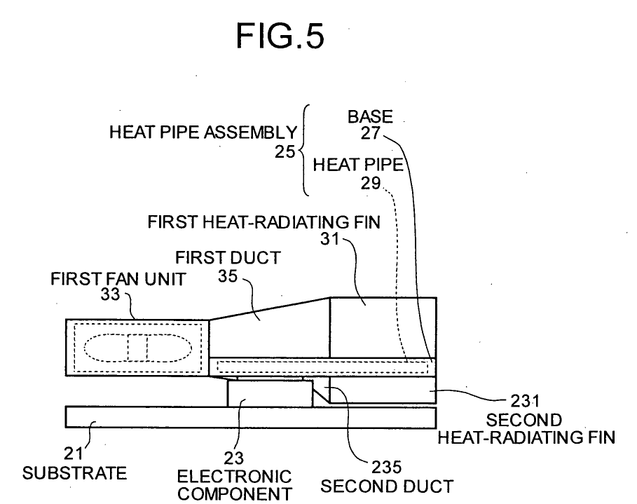

A fourth embodiment is described with reference to FIG. 5. The components in the fourth embodiment that perform same or similar function or that have same or similar configuration as those in the first embodiment are denoted by the same reference numerals as the first embodiment, and overlapping descriptions are omitted.

A second heat-radiating fin 231 is provided opposite to the first heat-radiating fin 31 on the other side of the planer heat pipe assembly 25 (the planer heat pipe 29). Further, a second duct 235 that guides an airflow produced by the first fan unit 33 to the second heat-radiating fin 231 is provided.

According to the above configuration, heat is discharged from both the first heat-radiating fin 31 and the second heat-radiating fin 231, so that the total amount of discharged heat increases and the cooling ability is improved. Moreover, the device is compact.

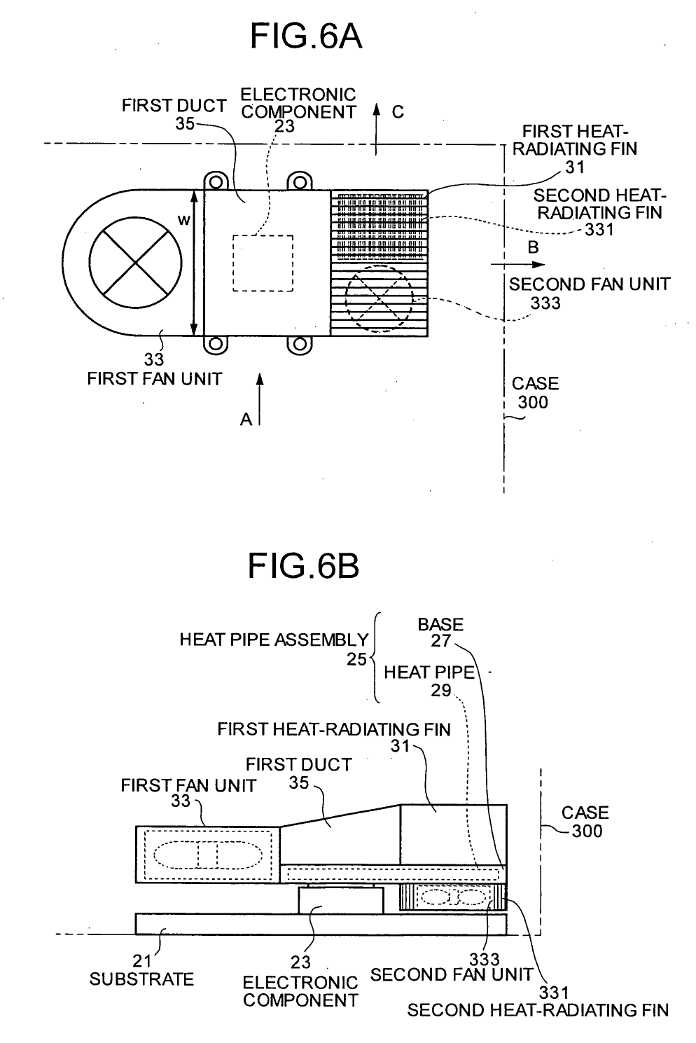

A fifth embodiment is described with reference to FIGS. 6A and 6B. FIG. 6A is a top view, and FIG. 6B is a view in a direction indicated by an arrow A shown in FIG. 6A. The components in the fifth embodiment that perform same or similar function or that have same or similar configuration as those in the first embodiment are denoted by the same reference numerals as the first embodiment, and overlapping descriptions are omitted.

A cooling device of an electronic component according to the fifth embodiment is provided in a corner of a case 300. A second heat-radiating fin 331 is provided opposite to the first heat-radiating fin 31 on the other side of the heat pipe assembly 25. Further, a second fan unit 333 that sends an airflow to the second heat-radiating fin 331 is provided on the other side of the heat pipe assembly 25. In the fifth embodiment, the fin of the second heat-radiating fin 331 is in a direction substantially orthogonal to a direction of the fin of the first heat-radiating fin 31.

According to the above configuration, similarly to the fourth embodiment, heat is discharged from both the first heat-radiating fin 31 and the second heat-radiating fin 331, so that the total amount of discharged heat increases and the cooling ability is improved. Further, the second fan unit 333 that sends an airflow to the second heat-radiating fin 331 is provided so that the cooling ability is further improved. Moreover, the device is compact.

In the fifth embodiment, the fin of the second heat-radiating fin 331 is in the direction substantially orthogonal to the direction of the fin of the first heat-radiating fin 31, and therefore, an airflow produced by the first fan unit 33 flows in a direction indicated by an arrow B, and an airflow produced by the second fan unit 333 flows in a direction indicated by an arrow C substantially orthogonal to the arrow B, as shown in FIG. 6A. Further, the cooling device of the electronic component is provided in the corner of the case 300. Therefore, heat of the electronic component is transferred to air and discharged from two adjacent surfaces of the case 300. Accordingly, the air to which the heat of the electronic component is transferred is efficiently discharged from the case 300.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A cooling device comprising:
a planar heat pipe;
an attaching member that attaches an electronic component to one surface on one side of the heat pipe so that the heat pipe can absorb heat of the electronic component, the electronic component being provided on a substrate;
a heat-radiating fin attached to another surface on another side of the heat pipe, the another side is made to slant towards the substrate;
a fan unit that produces an airflow and directs the airflow towards the heat-radiating fin; and
a duct that guides the airflow produced by the fan unit to the heat-radiating fin.

2. An electronic device comprising:
an electronic component; and
a cooling unit including
a planar heat pipe;
an attaching member that attaches the electronic component to one surface on one side of the heat pipe so that the heat pipe can absorb heat of the electronic component, the electronic component being provided on a substrate;
a heat-radiating fin attached to another surface on another side of the heat pipe, the another side is made to slant towards the substrate;
a fan unit that produces an airflow and directs the airflow toward the heat-radiating fin; and
a duct that guides the airflow produced by the fan unit to the heat-radiating fin.
